(19) United States
(12) Patent Application Publication
(10) Pub. No.: US 2017/0294459 A1
(43) Pub. Date: Oct. 12, 2017

(54) DISPLAY DEVICE

(71) Applicant: InnoLux Corporation, Miao-Li County (TW)

(72) Inventor: Kuan-Feng LEE, Miao-Li County (TW)

(21) Appl. No.: 15/452,754

(22) Filed: Mar. 8, 2017

Related U.S. Application Data
(60) Provisional application No. 62/319,965, filed on Apr. 8, 2016.

(30) Foreign Application Priority Data
Oct. 9, 2016 (CN) 201610878503.8

(51) Int. Cl. H01L 27/12; G02F 1/1362; H01L 29/49; G02F 1/1368; H01L 29/786; H01L 29/51

(52) U.S. Cl. CPC H01L 27/1251; H01L 27/1222; H01L 27/1225; H01L 29/7869; H01L 29/78696; H01L 29/7866; H01L 29/518; H01L 27/1218; H01L 29/4908; G02F 1/1368; G02F 1/13624; H01L 27/3262

(57) ABSTRACT

A display device includes: a substrate; a first thin film transistor unit disposed on the substrate and comprising a first active layer comprising a silicon layer, wherein the first active layer comprises a channel region, a source region and a drain region; a second thin film transistor unit disposed on the substrate and comprising a second active layer comprising a metal oxide layer; and a display medium disposed on the first thin film transistor unit and the second thin film transistor unit. Herein, a thickness of the silicon layer in the channel region is less than or equal to a thickness of the silicon layer in the source region.

### CROSS REFERENCE TO RELATED APPLICATION

This application claims the benefit of filing date of U. S. Provisional Application Ser. No. 62/319,965, filed Apr. 8, 2016 under 35 USC §119(e)(1).

This application claims the benefits of the Chinese Patent Application Serial Number 201610878503.8, filed on Oct. 9, 2016, the subject matter of which is incorporated herein by reference.

### BACKGROUND

### 1. Field of the Disclosure

The present disclosure relates to display devices, and more particularly to a display device that contains both a low-temperature polysilicon thin film transistor unit and a metal oxide layer thin film transistor unit.

### 2. Description of Related Art

With the continuous progress of display technology, the current trend is to make display panels as compact, thin and light as possible. Thin displays, such as liquid crystal display panels, organic light-emitting diode display panels and inorganic light-emitting diode display panels, have become dominant in the market instead of their predecessors based on cathode ray tubes. Thin displays are extensively applicable. For example, mobile phones, laptop computers, video cameras, still cameras, music players, mobile navigators and TV sets are just a few devices that use such a display panel.

Liquid crystal display devices and organic light-emitting diode display device have been popular in the market and liquid crystal display devices are particularly well developed. However, in view of the consumers' increasing requirements to display quality of display devices, almost every maker in this industry is investing in advancing display devices particularly in terms of display quality.

Thin film transistors in a display device's display region are either polysilicon thin film transistors having high carrier mobility, or metal oxide layer thin film transistors featuring low current leakage. The complexity of combining, the less compatible manufacturing processes of these two kinds of thin film transistors, such as requiring increased repetitions of chemical vapor deposition, prevents an existing display device to use both of them. In view of this, the thin film transistor elements used in the display region and in the area having the circuit that drives the gate electrode in the display region need to be structurally improved, so as to maintain good properties and have their manufacturing and configuration simplified. In addition, since the existing low-temperature polysilicon thin film transistors tend to have leakage current, this element needs to be structurally improved to prevent leakage current and enhance its efficiency.

### SUMMARY

An objective of the present disclosure is to provide a display device that comprises both a low-temperature polysilicon thin film transistor unit and a metal oxide layer thin film transistor unit.

In one embodiment of the present disclosure, the display device comprises: a substrate; a first thin film transistor unit disposed on the substrate and comprising: a first active layer comprising a silicon layer, wherein the first active layer comprises a channel region, a source region and a drain region; a second thin film transistor unit disposed on the substrate and comprising: a second active layer comprising a metal oxide layer; and a display medium layer disposed on the first thin film transistor unit and the second thin film transistor unit. Herein, a thickness of the silicon layer in the channel region is less than or equal to a thickness of the silicon layer in the source region.

As stated previously, the disclosed display device comprises both the first thin film transistor unit whose first active layer comprises a polysilicon layer and the second thin film transistor unit whose second active layer comprises a metal oxide layer. Particularly, the first active layer of the first thin film transistor unit comprises the polysilicon layer and the amorphous silicon layer that has the doped region and the non-doped region. The non-doped region is disposed between the polysilicon layer and the doped region. Such configuration allows the first thin film transistor unit whose first active layer comprises a polysilicon layer to have low current leakage.

Other objects, advantages, and novel features of the present disclosure will become more apparent from the following detailed description when taken in conjunction with the accompanying drawings.

### BRIEF DESCRIPTION OF THE DRAWINGS

FIG. 1A through FIG. 1E are cross-sectional views of a display device according to Embodiment 1 of the present disclosure showing the flow in which elements are formed on its substrate.

FIG. 1F is a cross-sectional view of the display device according to Embodiment 1 of the present disclosure.

FIG. 2A through FIG. 2D are cross-sectional views of a display device according to Embodiment 2 of the present disclosure showing the flow in which elements are formed on its substrate.

FIG. 3A through FIG. 3F are cross-sectional views of a display device according to Embodiment 3 of the present disclosure showing the flow in which elements are formed on its substrate.

FIG. 4 is a cross-sectional view of a display device according to Embodiment 4 of the present disclosure showing elements on its substrate.

FIG. 5 is a cross-sectional view of a display device according to Embodiment 5 of the present disclosure showing elements on its substrate.

FIG. 6 is a cross-sectional view of a display device according to Embodiment 6 of the present disclosure showing elements on its substrate.

FIG. 7A through FIG. 7C are cross-sectional views of a display device according to Alternative Embodiment 1 of the present disclosure showing elements on its substrate.

FIG. 8 is a cross-sectional view of a display device according to Alternative Embodiment 2 of the present disclosure showing elements on its substrate.

### DETAILED DESCRIPTION OF EMBODIMENT

The following embodiments when read with the accompanying drawings are made to clearly exhibit the abovementioned and other technical contents, features and effects of the present disclosure. Through the exposition by means of the specific embodiments, people would further understand the technical means and effects the present disclosure adopts to achieve the above-indicated objectives. Moreover, as the contents disclosed herein should be readily understood and can be implemented by a person skilled in the art, all equivalent changes or modifications which do not depart from the concept of the present disclosure should be encompassed by the appended claims.

As used in the different embodiments of the present disclosure, the term “over” or “on” broadly encompasses a layer being “directly on or over,” e.g., contacting, or “indirectly on or over,” e.g., not contacting, another layer. Also, unless otherwise specified, the term “under” broadly encompasses “directly under” and “indirectly under.”

Furthermore, the ordinals recited in the specification and the claims such as “first”, “second” and so on are intended only to describe the elements claimed and imply or represent neither that the claimed elements have any preceding ordinals, nor that sequence between one claimed element and another claimed element or between steps of a manufacturing method. The use of these ordinals is merely to differentiate one claimed element having a certain designation from another claimed element having the same designation.

### Embodiment 1

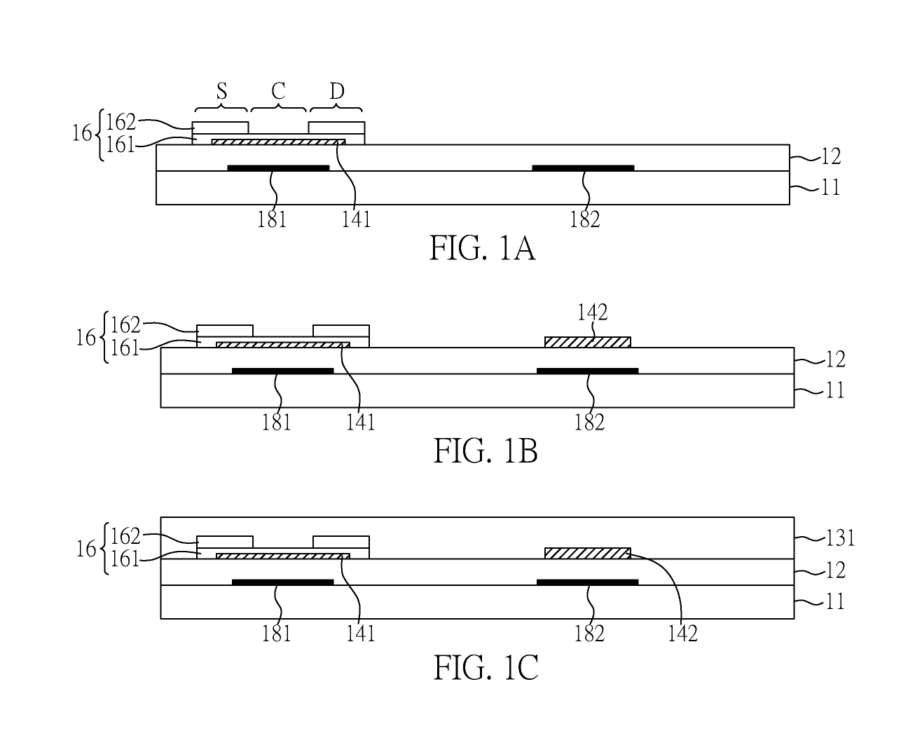

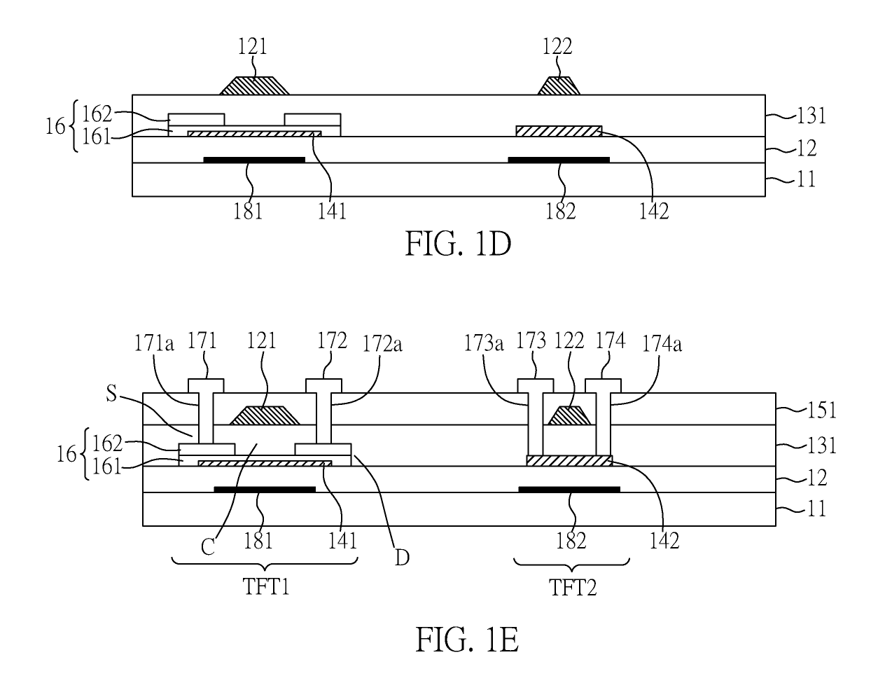

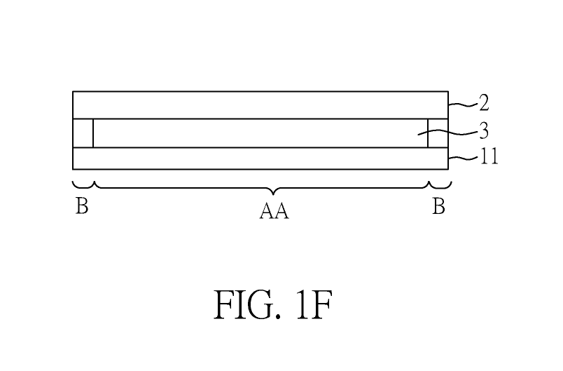

FIG. 1A through FIG. 1E are cross-sectional views of a display device according to the present embodiment showing the flow in which elements are formed on its substrate. First, as shown in FIG. 1A, a substrate 11 is provided. Herein, the substrate 11 is made of glass, plastic, or a flexible material. On the substrate 11, a first mask layer 181 and a second mask layer 182 are disposed. The first mask layer 181 and the second mask layer 182 may be made of any optical shutter material, such as metal, a black matrix or the like. Then a buffering layer 12 is disposed on the first mask layer 181 and the second mask layer 182. The buffering layer 12 may be made of silicon oxide or may be a stacked structure formed by silicon nitride and silicon oxide, in which case silicon nitride is disposed between silicon oxide and the substrate. Afterward, a patterned polysilicon layer 141 is disposed on the buffering layer 12 so that the polysilicon layer 141 corresponds to the first mask layer 181. An amorphous silicon layer 16 disposed on the polysilicon layer 141 comprises a doped region 162 and a non-doped region 161. The polysilicon layer 141 and the amorphous silicon layer 16 form a first active layer. The first active layer comprises a channel region C, a source region S, and a drain region D. The channel region C is disposed between the source region S and the drain region D. A thickness of the silicon layer 16 in the channel region C can be less than or equal to a thickness of the silicon layer 16 in the source region S or in the drain region D. In the present embodiment, the thickness of the silicon layer 16 in the channel region C is less than the thickness of the silicon layer 16 in the source region S or in the drain region D. The channel region C has the non-doped region 161 but does not have the doped region 162. The source region S and the drain region comprise both the doped region 162 and the non-doped region 161, and the non-doped region 161 is between the doped region 162 and the polysilicon layer 141.

As shown in FIG. 1B, a second active layer 142 is formed on the first buffering layer 12. The second active layer 142 and the second mask layer 182 correspond to each other. Furthermore, in the present embodiment, the second active layer 142 is a metal oxide layer, such as an IGZO layer. As shown in FIG. 1C, a first gate insulating layer 131 is formed on the first active layer and the second active layer 142. The first gate insulating layer 131 is a silicon oxide layer or may be a stacked structure formed by silicon nitride and silicon oxide. As shown in FIG. 1D, a first gate electrode 121 and a second gate electrode 122 are simultaneously formed on first gate insulating layer 131. The first gate electrode 121 and the second gate electrode 122 correspond to the first active layer and the second active layer 142, respectively. Additionally, the first gate electrode 121 and the second gate electrode 122 may be made of a metal material such as Cu, Al, Ti, Mo, MoN, TiN, or combination thereof. As shown in FIG. 1E, a first insulating layer 151 is formed on the first gate electrode 121 and the second gate electrode 122. The first insulating layer 151 in the present embodiment is made of silicon oxide or may be a stacked structure formed by silicon nitride and silicon oxide. A first source electrode 171 and a first drain electrode 172 are formed on the first insulating layer 151 so that the first source electrode 171 and the first drain electrode 172 electrically connect to the doped regions 162 of the amorphous silicon layers 16 in the source region S and the drain region D through a plurality of contact holes 171a, 172a, respectively. A second source electrode 173 and a second drain electrode 174 are formed on the first insulating layer 151. The second source electrode 173 and the second drain electrode 174 electrically connect to the second active layer 142 through a plurality of contact holes 173a, 174a.

Through the foregoing process, in the display device of the present embodiment, the first active layer (comprising the polysilicon layer 141 and the amorphous silicon layer 16) and the second active layer 142 are disposed on the substrate 11. The first gate insulating layer 131 is disposed on the first active layer and the second active layer 142. The first gate electrode 121 and the second gate electrode 122 are disposed on the first gate insulating layer 131. A first insulating layer 151 is disposed on the first gate electrode 121 and the second gate electrode 122. The first source electrode 171, the first drain electrode 172, the second source electrode 173, and the second drain electrode 174 are disposed on the first insulating layer 151. The first source electrode 171 and the first drain electrode 172 electrically connect to the doped regions 162 of the amorphous silicon layers 16 in the source region S and in the drain region D through a plurality of contact holes 171a, 172a. The second source electrode 173 and the second drain electrode 174 electrically connect to the second active layer 142 through a plurality of contact holes 173a, 174a. In addition, the display device further comprises a first mask layer 181, a second mask layer 182, and a buffering layer 12. The first mask layer 181 and the second mask layer 182 are disposed between the substrate 11 and the buffering layer 12. The first active layer and the second active layer 142 are disposed on the buffering layer 12. The first active layer and the second active layer 142 overlap the first mask layer 181 and the second mask layer 182, respectively. Moreover, in the present embodiment, the non-doped region 161 is further disposed in the channel region C. A thickness of the non-doped region 161 in the channel region C is less than or equal to a thickness of the non-doped regions 161 in the source region S or in the drain region D.

In the present embodiment, the display device comprises both the first thin film transistor unit TFT1 whose first active layer has a polysilicon layer 141 and the second thin film transistor unit TFT2 whose second active layer 142 has a metal oxide layer. The metal oxide layer may be a zinc-oxide-based metal oxide layer, such as a layer of IGZO, ITZO, IGZTO or the like. The first thin film transistor unit TFT1 is of a top gate structure and comprises a first gate electrode 121. The first gate electrode 121 is disposed on the first active layer. Particularly, in the present embodiment, the first active layer and the second active layer are disposed on the same layer, the first gate electrode and the second gate electrode can be formed simultaneously, while the first source electrode, the second source electrode, the first drain electrode and the second drain electrode can also be formed simultaneously, thereby simplifying both manufacturing and configuration on the substrate. Besides, the flow of the present embodiment in which the polysilicon layer is made before the metal oxide layer prevents the metal oxide layer from being damaged by the high-temperature crystallization process used to make the polysilicon layer. Alternatively, the first thin film transistor unit whose first active layer has the polysilicon layer as produced in the present embodiment has lower leakage current.

As shown in FIG. 1F, the display device of the present embodiment may further comprise a second substrate 2 opposite to the substrate 11. A display medium layer 3 is disposed between the substrate 11 and the second substrate 2, and on the first thin film transistor unit and the second thin film transistor unit. The substrate 11 and the second substrate 2 may be made of glass, plastic, a flexible material, or thin film. In addition, the display medium layer 3 may be a liquid crystal layer, an organic light-emitting layer or a light emitting diode chip array, but is not limited thereto.

### Embodiment 2

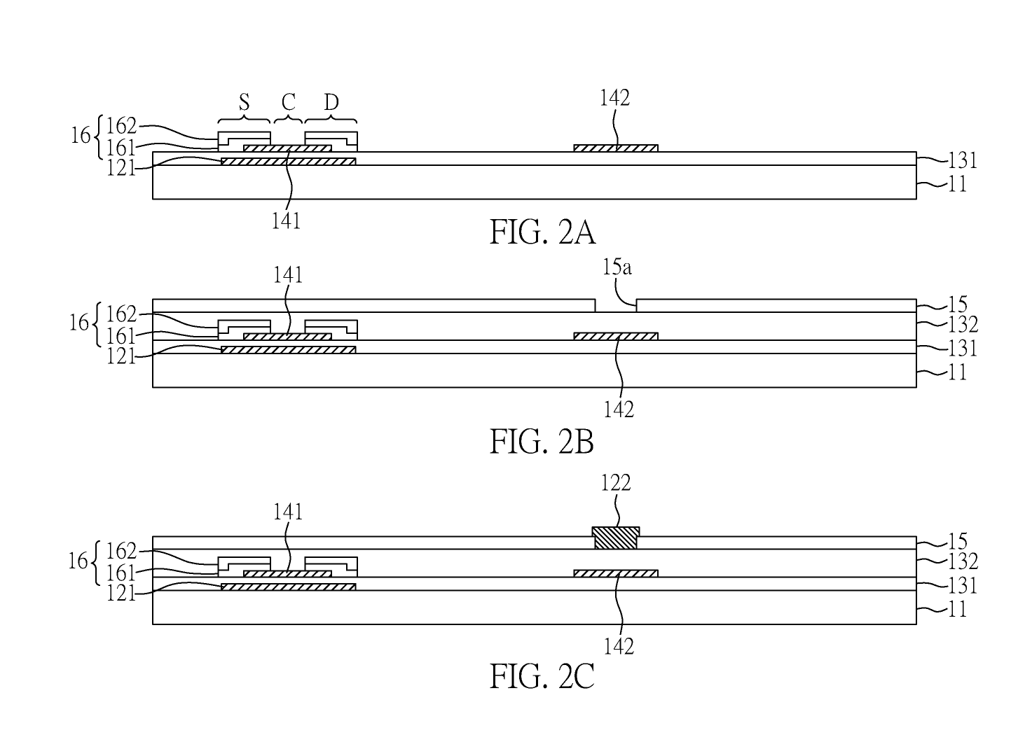

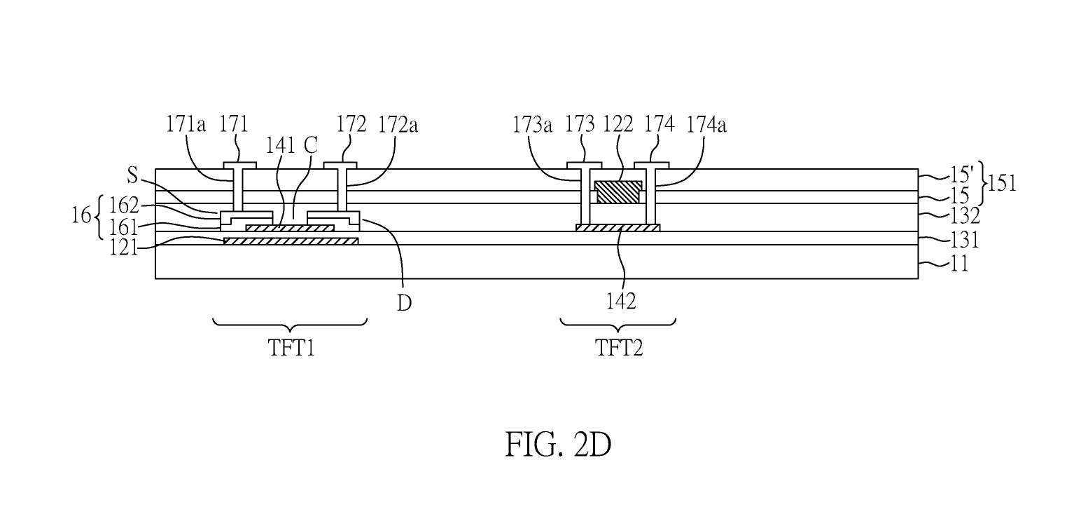

FIG. 2A through FIG. 2D are cross-sectional views of a display device according to the present embodiment showing the flow in which elements are formed on its substrate. First, as shown in FIG. 2A, a substrate 11 is provided. A patterned first gate electrode 121 is disposed on the substrate 11. A first gate insulating layer 131 is disposed on the substrate 11 and the first gate electrode 121. A first active layer is disposed on the first gate insulating layer 131. The first active layer corresponds to the first gate electrode 121. The first active layer comprises a polysilicon layer 141 and an amorphous silicon layer 16. The polysilicon layer 141 is disposed between the substrate 11 and the amorphous silicon layer 16. The first active layer comprises a source region S, a drain region D, and a channel region C. The channel region C is disposed between the source region S and the drain region D. The amorphous silicon layer 16 comprises a doped region 162 and a non-doped region 161. The non-doped region 161 and the doped region 162 are successively stacked on the polysilicon layer 141 and disposed in the source region S and in the drain region D. A second active layer 142 is disposed on the first gate insulating layer 131. The second active layer is a metal oxide layer, such as an IGZO layer. As shown in FIG. 2B, a second gate insulating layer 132 is formed on the first active layer (comprising polysilicon layer 141 and the amorphous silicon layer 16) and the second active layer 142. Then a bottom insulating layer 15 is formed on the second gate insulating layer 132. The bottom insulating layer 15 in the present embodiment is a silicon nitride layer. An opening 15a is formed on the bottom insulating layer 15 to expose the second gate insulating layer 132. The opening 15a corresponds to the second active layer 142. As shown in FIG. 2C, a second gate electrode 122 is formed on the bottom insulating layer 15. The second gate electrode 122 is disposed in the opening 15a of the bottom insulating layer 15, and the second gate electrode 122 corresponds to the second active layer 142. The second gate electrode 122 may be made of a metal material such as Cu, Al, Ti, Mo, MoN, TiN, or combination thereof. As shown in FIG. 2D, a top insulating layer 15′ is formed on the second gate electrode 122 and the bottom insulating layer 15. The top insulating layer 15′ is a silicon oxide layer. The bottom insulating layer 15 and the top insulating layer 15′ form a first insulating layer 151. Then a first source electrode 171 and a first drain electrode 172 are formed on the first insulating layer 151 so that the first source electrode 171 and the first drain electrode 172 electrically connect to and the doped regions 162 of the amorphous silicon layers 16 in the source region S and in the drain region D through a plurality of contact holes 171a, 172a, respectively. A second source electrode 173 and a second drain electrode 174 are formed on the first insulating layer 151 so that the second source electrode 173 and the second drain electrode 174 electrically connect to the second active layer 142 through a plurality of contact holes 173a, 174a.

The display device of the present embodiment made using the process described above comprises a first gate electrode 121 disposed on the substrate 11. The first gate insulating layer 131 is disposed on the first gate electrode 121. The first active layer (comprising the polysilicon layer 141 and the amorphous silicon layer 16) and the second active layer 142 are disposed on the first gate insulating layer 131. The second gate insulating layer 132 is disposed on the first active layer and the second active layer 142. The second gate electrode 122 is disposed on the second gate insulating layer 132. A first insulating layer 151 is disposed on the second gate insulating layer 132. The first source electrode 171, the first drain electrode 172, the second source electrode 173, and the second drain electrode 174 are disposed on the first insulating layer 151. The first source electrode 171 and the first drain electrode 172 electrically connect to the doped regions 162 of the amorphous silicon layers 16 in the source region S and in the drain region D through a plurality of contact holes 171a, 172a. The second source electrode 173 and the second drain electrode 174 electrically connect to the second active layer 142 through a plurality of contact holes 173a, 174a. In the present embodiment, the first insulating layer 151 comprises a bottom insulating layer 15 and a top insulating layer 15′. The bottom insulating layer 15 is disposed between the second gate insulating layer 132 and the top insulating layer 15′. The second gate electrode 122 is disposed in the opening 15a (as indicated in FIG. 2B) of the bottom insulating layer 15 and in contact with the second gate insulating layer 132. The opening 15a corresponds to the second active layer 142. Additionally, the bottom insulating layer 15 in the present embodiment is a silicon nitride layer and the top insulating layer is a silicon oxide layer. The bottom insulating layer 15 as a silicon nitride layer contains more hydrogen than the top insulating layer 15′ as a silicon oxide layer. Removing the bottom insulating layer 15 above the metal oxide layer prevents hydrogen in the bottom insulating layer 15 from spreading into the metal oxide layer, and in turn prevents the metal oxide layer from being more conductive and degrading the efficiency of the thin film transistor.

### Embodiment 3

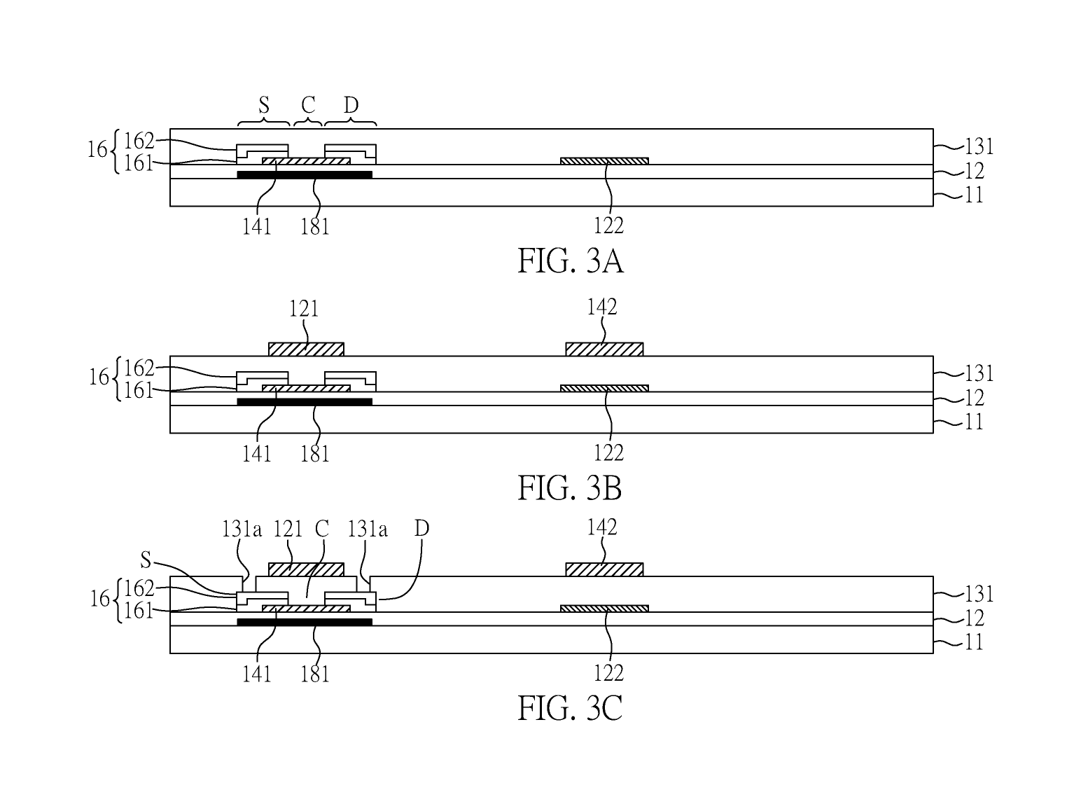

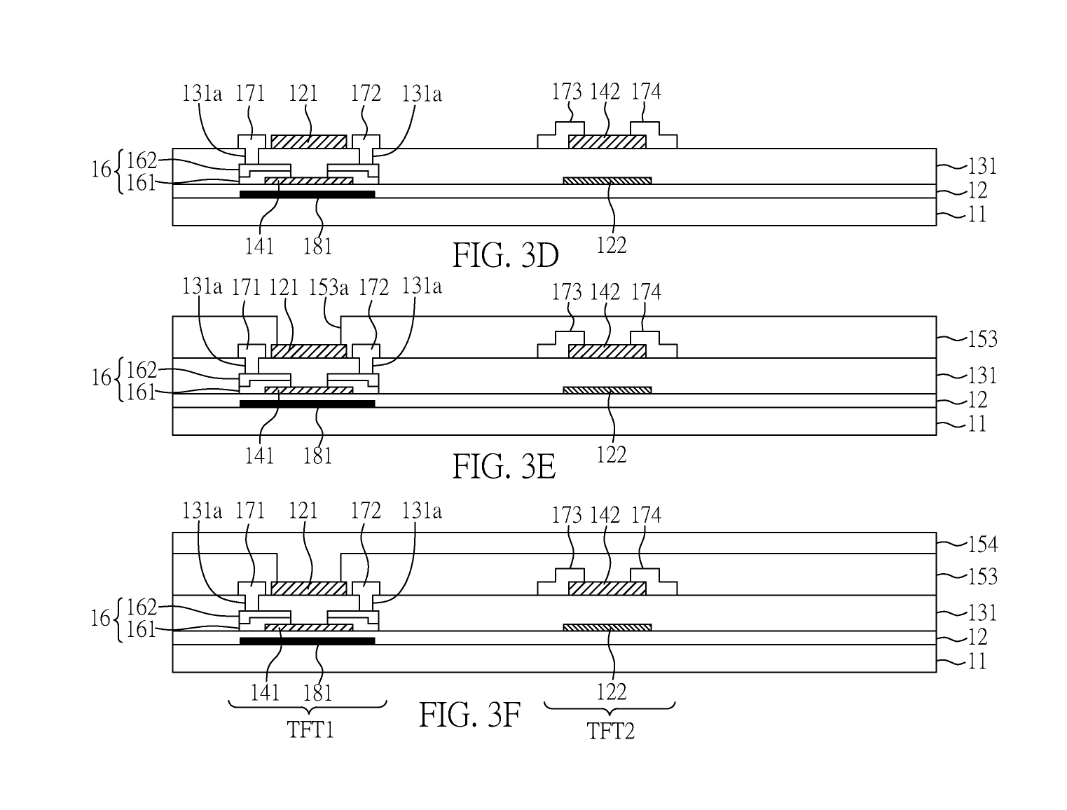

FIG. 3A through FIG. 3F are cross-sectional views of a display device according to the present embodiment showing the flow in which elements are formed on its substrate. First, as shown in FIG. 3A, a substrate 11 is provided. Herein, the substrate 11 is made of glass, plastic, or a flexible material. A patterned first mask layer 181 is formed on the substrate. Then a buffering layer 12 is formed on the first mask layer 181. The buffering layer 12 may be made of silicon oxide or may be a stacked structure formed by silicon nitride and silicon oxide, in which case silicon nitride is disposed between silicon oxide and the substrate. Afterward, a patterned polysilicon layer 141 is disposed on the first buffering layer 12. The polysilicon layer 141 and the first mask layer 181 correspond to each other. An amorphous silicon layer 16 is then formed on the polysilicon layer 141. It comprises a doped region 162 and a non-doped region 161. The doping is to form an n-type amorphous silicon layer. The polysilicon layer 141 and the amorphous silicon layer 161 form a first active layer that comprises a source region S, a drain region D, and a channel region C. The source region S and the drain region D have the amorphous silicon layer 16. A second gate electrode 122 is formed on the buffering layer 12. In the present embodiment, the second gate electrode 122 is made of polysilicon. A first gate insulating layer 131 is formed on the first active layer and the second gate electrode 122. The first gate insulating layer 131 is a silicon oxide layer. As shown in FIG. 3B, a first gate electrode 121 and a second active layer 142 are disposed on the first gate insulating layer 131. In the present embodiment, the first gate electrode 121 and the second active layer 142 are each a metal oxide layer, such as an IGZO layer. As shown in. FIG. 3C, an opening 131a is formed in the first gate insulating layer 131 to expose the doped regions 162 of the amorphous silicon layers 16 in the source region S and in the drain region D. As shown in FIG. 3D, a first source electrode 171 and a first drain electrode 172 are formed on the first gate insulating layer 131 so that the first source electrode 171 and the first drain electrode 172 electrically connect to the doped regions 162 of the amorphous silicon layers 16 in the source region S and in the drain region D through the opening 131a, respectively. A second source electrode 173 and a second drain electrode 174 are formed on the first gate insulating layer 131. The second source electrode 173 and the second drain electrode 174 electrically connect to the second active layer 142.

As shown in FIG. 3E, a third insulating layer 153 is formed on the first source electrode 171, the first drain electrode 172, the first gate electrode 121, the second source electrode 173, the second drain electrode 174, and the second active layer 142. An opening 153a is formed in the third insulating layer 153 to expose the first gate electrode 121. The third insulating layer 153 in the present embodiment is a silicon oxide layer. As shown in FIG. 3F, a fourth insulating layer 154 is formed on the third insulating layer 153 and in the opening 153a of the third insulating layer. The fourth insulating layer 154 and the first gate electrode 121 are at the opening 153a of the third insulating layer, and the fourth insulating layer 154 contacts the first gate electrode 121. In the present embodiment the fourth insulating layer 154 is a silicon nitride layer.

The display device of the present embodiment made using the process described above comprises a first active layer (comprising the polysilicon layer 141 and the amorphous silicon layer 16) and the second gate electrode 122 disposed on the substrate 11. The first gate insulating layer 131 is disposed on the first active layer and the second gate electrode 122. The first gate electrode 121 and the second active layer 142 are disposed on the first gate insulating layer 131. The first source electrode 171 and the first drain electrode 172 are disposed on the first gate insulating layer 131 and electrically connect to the doped regions 162 of the amorphous silicon layers 141 in the source region S and in the drain region. D through the openings 131a formed in the first gate insulating layer 131 as contact holes. The second source electrode 173 and the second drain electrode 174 are disposed on the second active layer 142 and electrically connect to the second active layer 142. Therein, the first gate electrode 121 comprises a metal oxide layer, such as an IGZO layer. The second gate electrode 122 comprises a silicon layer, such as a polysilicon layer. In addition, a third insulating layer 153 is disposed on the first gate insulating layer 131, first gate electrode 121, the first source electrode 171, the first drain electrode 172, the second active layer 142, the second source electrode 173, and the second drain electrode 174. The third insulating layer 153 comprises an opening 153a to expose the first gate electrode 121, and a fourth insulating layer 154 is disposed on the third insulating layer 153 and in the opening 153a. The fourth insulating layer 154 is made of silicon nitride. In addition, there are further a first mask layer 181 and a buffering layer 12. The first mask layer 181 is disposed between the substrate 11 and the buffering layer 12. The first active layer and the second gate electrode 122 are disposed on the buffering layer 12. The first active layer overlaps the first mask layer 181.

In the present embodiment, the display device comprises both the first thin film transistor unit TFT1 of the first active layer comprising polysilicon layer 141 and the second thin film transistor unit TFT2 of the second active layer 142 as a metal oxide layer. The first gate electrode 121 included in the first thin film transistor unit TFT1 is disposed above the first active layer, thereby forming a top gate electrode structure. The second gate electrode 122 included in the second thin film transistor unit TFT2 is disposed below the second active layer 142, thereby forming a bottom gate structure. Particularly, in the present embodiment, the polysilicon layer 142 and the second gate electrode 122 can be formed simultaneously, and the first gate electrode 121 and the second active layer 142 can be formed simultaneously, thereby simplifying both manufacturing and configuration on the substrate. Furthermore, in the present embodiment, the fourth insulating layer 154 is a silicon nitride layer, and the fourth insulating layer 154 contacts the first gate electrode 121 through the opening 153a in the third insulating layer 153. The first gate electrode 121 in the present embodiment is formed by a metal oxide layer, such as an IGZO layer. Since the silicon nitride layer contains hydrogen, when the silicon nitride layer contacts the first gate electrode, hydrogen in the silicon nitride layer spreads into IGZO, so that the activity of IGZO is enhanced and its conductivity in turn increases.

### Embodiment 4

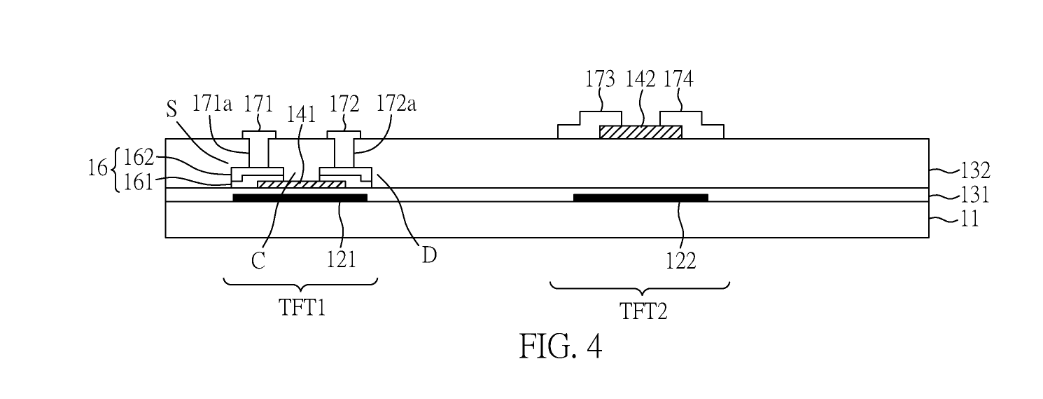

The manufacturing process used in the present embodiment is similar to those described in the previous embodiments, and thus detailed discussion thereto is omitted. As shown in FIG. 4, the display device of the present embodiment comprises the first gate electrode 121 and the second gate electrode 122 disposed on the substrate 11. The first gate insulating layer 131 is disposed on the first gate electrode 121 and the substrate 11. The first active layer (comprising the polysilicon layer 141 and the amorphous silicon layer 16) is disposed on the first gate insulating layer 131. The second gate insulating layer 132 is disposed on the first active layer and the second gate electrode 122. The first source electrode 171 and the first drain electrode 172 are disposed on the second gate insulating layer 132 and electrically connect to the doped regions 162 of the amorphous silicon layers 16 in the source region S and in the drain region D through a plurality of contact holes 171a, 172a. The second active layer 142 is disposed on the second gate insulating layer 132. The second source electrode 173 and the second drain electrode 174 are disposed on the second active layer 142 and electrically connect to the second active layer 142. Therein, the second gate electrode 122 is disposed between the first gate insulating layer 131 and the substrate 11. In the present embodiment, the first gate electrode 121 included in the first thin film transistor unit TFT1 is disposed below the first active layer, and the second gate electrode 122 included in the second thin film transistor unit TFT2 is disposed below the second active layer 142, both of which are of a bottom gate structure. Additionally, the second gate electrode 122 included in the second thin film transistor unit TFT2 and the first gate electrode 121 included in the first thin film transistor unit TFT1 are formed simultaneously, thereby simplifying both manufacturing and configuration on the substrate. Moreover, in the present embodiment, the first gate electrode 121 and the second gate electrode 122 are made of metal material such as Cu, Al, Ti, Mo, MoN, TiN, or combination thereof.

### Embodiment 5

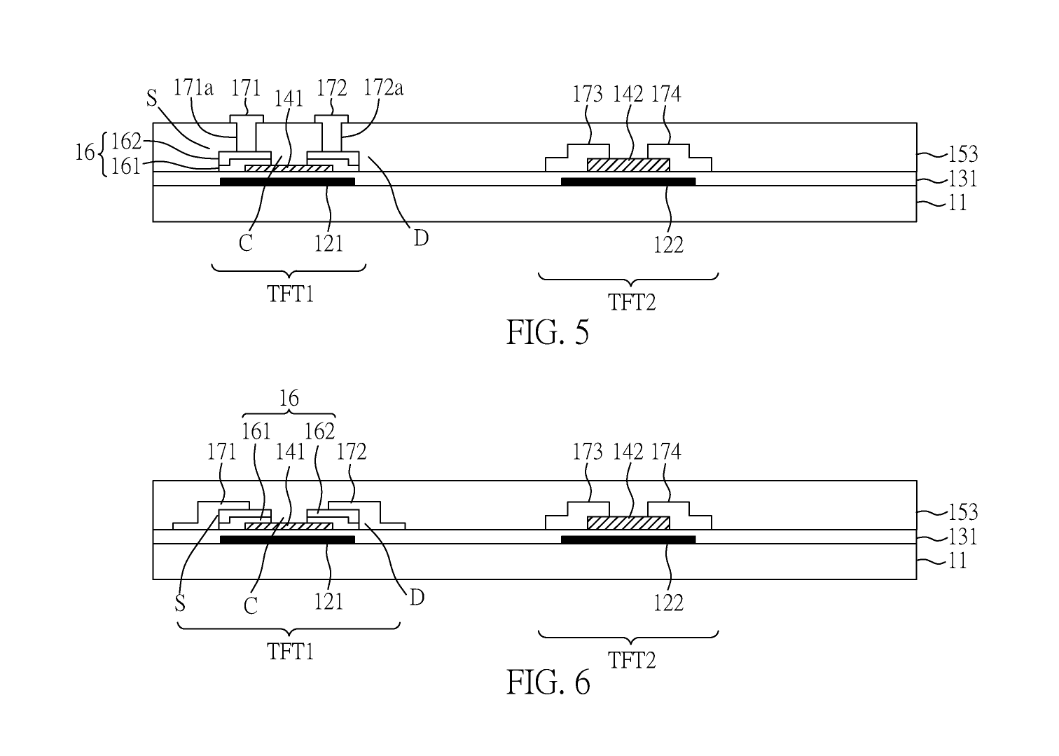

The manufacturing process used in the present embodiment is similar to those described in the previous embodiments, and thus detailed discussion thereto is omitted. As shown in FIG. 5, the display device of the present embodiment, comprising: a first gate electrode 121 and the second gate electrode 122 is disposed on the substrate 11. The first gate insulating layer 131 is disposed on the first gate electrode 121, the second gate electrode 122, and the substrate 11. The first active layer (comprising the polysilicon layer 141. and the amorphous silicon layer 16) and the second active layer 142 are disposed on the first gate insulating layer 131. The second source electrode 173 and the second drain electrode 174 are disposed on the second active layer 142 and electrically connect to the second active layer 142. A third insulating layer 153 is disposed on the first gate insulating layer 131, the second active layer 142, the second source electrode 173, and the second drain electrode 174. The first source electrode 171 and the first drain electrode 172 are disposed on the third insulating layer 153 and electrically connect to the doped regions 162 of the amorphous silicon layers 16 in the source region S and in the drain region D through a plurality of contact holes 171a, 172a.

### Embodiment 6

The manufacturing process used in the present embodiment is similar to those described in the previous embodiments, and thus detailed discussion thereto is omitted. As shown in FIG. 6, the display device of the present embodiment comprises: a first gate electrode 121 and the second gate electrode 122 disposed on the substrate 11. The first gate insulating layer 131 is disposed on the first gate electrode 121, the second gate electrode 122, and the substrate 11. The first active layer (comprising the polysilicon layer 141 and the amorphous silicon layer 16) and the second. active layer 142 are disposed on the first gate insulating layer 131. The second source electrode 173 and the second drain electrode 174 are disposed on the second active layer 142 and electrically connect to the second active layer 142. A third insulating layer 153 is disposed on the first active layer, the second active layer 142, the second source electrode 173 and the second drain electrode 174. The first source electrode 171 and the first drain electrode 172 are disposed on the doped regions 162 of the amorphous silicon layers 16 in the source region S and in the drain region D and connects to the doped region 162.

### Alternative Embodiment 1

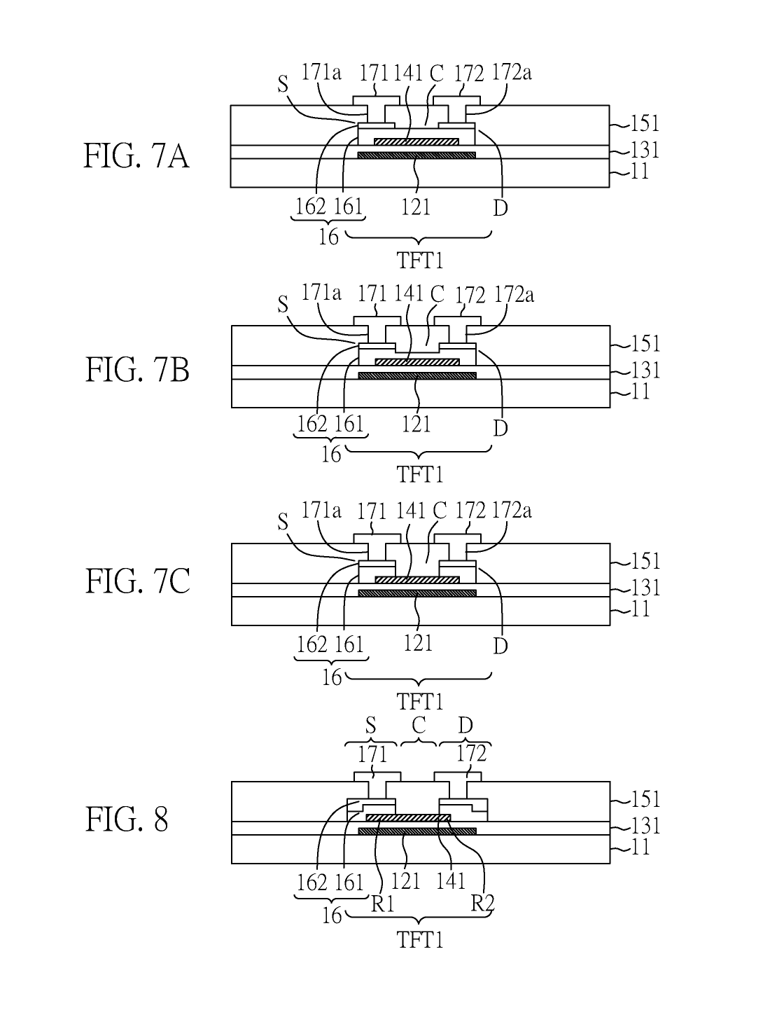

The display device of the present disclosure as any one described in Embodiment 1 through Embodiment 6 comprises a first thin film transistor unit TFT1 whose first active layer has a polysilicon layer and an amorphous silicon layer. In Alternative Embodiment 1 of the present disclosure, the first active layer of the first thin film transistor unit TFT1 may have a structure different from those shown in the drawings of the previous embodiments. For example, the first thin film transistor unit may have structures shown in FIG. 7A. through FIG. 7C. Therein, the first active layer comprises a polysilicon layer 141 and an amorphous silicon layer 16. The amorphous silicon layer 16 comprises a doped region 162 and a non-doped region 161. The first active layer comprises a source region S, a drain region D, and a channel region C. The channel region C is disposed between the source region S and the drain region D. The amorphous silicon layer 16 is formed in the source region S and in the drain region D, and the channel region C does not include the doped region 162 of the amorphous silicon layer 16 but may optionally include the non-doped region 161 of the amorphous silicon layer 16. In FIG. 7A, a thickness of the non-doped region 161 in the channel region C is less than or equal to the thickness of the non-doped region 161 in the source electrode S and in the drain region D. In FIG. 7B, a thickness of the non-doped region 161 in the channel region C is less than a thickness of the non-doped region 161 in the source electrode S and in the drain region D. In FIG. 7C, the non-doped region 161 in the channel region is thinner than or equal to the non-doped region 161 in the source region and in the drain region. In the present disclosure, the aspects of FIG. 7A through FIG. 7C may be applied to Embodiment 1 through Embodiment 6 of the present disclosure.

### Alternative Embodiment 2

The display device of the present disclosure as any one described in Embodiment 1 through Embodiment 6 comprises a first thin film transistor unit TFT1 whose first active layer has a polysilicon layer 141 and an amorphous silicon layer 16. In Alternative Embodiment 2 of the present disclosure, the first active layer of the first thin film transistor unit TFT1 may have a structure different from those shown in the drawings of the previous embodiments. For example, the first thin film transistor unit TFT1 may have a structure as shown in FIG. 8. Therein, the first active layer comprises a polysilicon layer 141 and an amorphous silicon layer 16. The amorphous silicon layer 16 comprises a doped region 162 and a non-doped region 161. The first active layer comprises a source region S, a drain region D, and a channel region C. The channel region C is disposed between the source region S and the drain region D. The projected area of the polysilicon layer 141 in the source region S on the substrate 11 is different from that in the drain region D, as shown in FIG. 8. More specifically, the polysilicon layer 141 further comprises a first region R1 and a second region R2, the first region R1 and the first source electrode 171 overlap, the second region R2 and the first drain electrode 172 overlap, and an area of the first region R1 can be less than or equal to an area of the second region R2. In the present embodiment, the area of the first region R1 is equal to the area of the second region R2. The two areas may be in any ratios, and their relation is not limited to what shown in FIG. 8.

As shown in FIG. 1F, the display device of the present embodiment made using the process described above further comprises a display region AA and a periphery region B. The periphery region B is adjacent to the display region AA. In one embodiment, the first thin film transistor unit TFT1 is disposed in the periphery region B, while the second thin film transistor unit TFT2 is disposed in the display region AA. In another embodiment, the first thin film transistor unit TFT1 and the second thin film transistor unit TFT2 are disposed in the display region AA.

The display device of the present embodiment made using the process described above further has its display region provided with a plurality of pixels. In one embodiment, the first thin film transistor unit TFT1 and the second thin film transistor unit TFT2 are disposed in one of the pixels. In another embodiment, the pixels comprises a first pixel and a second pixel adjacent to the first pixel, wherein the first thin film transistor unit TFT1 is disposed in the first pixel and the second thin film transistor unit TFT2 is disposed in the second pixel.

In addition, a display device made as described in any of the embodiments of the present disclosure as described previously may be integrated with a touch panel to form a touch display device. Moreover, a display device or touch display device made as described in any of the embodiments of the present disclosure as described previously may be applied to any electronic devices known in the art that need a display screen, such as displays, mobile phones, laptops, video cameras, still cameras, music players, mobile navigators, TV sets, and other electronic devices that display images.

While the above embodiments are provided for illustrating the concept of the present disclosure, it is to be understood that these embodiments in no way limit the scope of the present disclosure which is defined solely by the appended claims.

What is claimed is:

1. A display device, comprising:
a substrate;
a first thin film transistor unit disposed on the substrate and comprising:
a first active layer comprising a silicon layer, wherein the first active layer comprises a channel region, a source region and a drain region;
a second thin film transistor unit disposed on the substrate and comprising:
a second active layer comprising a metal oxide layer; and
a display medium layer disposed on the first thin film transistor unit and the second thin film transistor unit;
wherein a thickness of the silicon layer in the channel region is less than or equal to a thickness of the silicon layer in the source region.

2. The display device of claim 1, wherein the silicon layer further comprises a polysilicon layer and an amorphous silicon layer, and the polysilicon layer is disposed between the substrate and the amorphous silicon layer.

3. The display device of claim 2, wherein the amorphous silicon layer has a doped region and a non-doped region between the doped region and the polysilicon layer.

4. The display device of claim 3, wherein a thickness of the non-doped region in the channel region is less than or equal to a thickness of the non-doped region in the source region or in the drain region.

5. The display device of claim 2, wherein the first thin film transistor unit further comprises a source electrode and a drain electrode, the polysilicon layer further comprises a first region and a second region, the first region and the source electrode overlap, the second region and the drain region overlap, and an area of the first region is greater than or equal to an area of the second region.

6. The display device of claim 1, further comprising a display region and a periphery region, wherein the periphery region is adjacent to the display region, the first thin film transistor unit is disposed in the periphery region, and the second thin film transistor unit is disposed in the display region.

7. The display device of claim 1, further comprising a display region and a periphery region, wherein the periphery region is adjacent to the display region, and the first thin film transistor unit and the second thin film transistor unit are disposed in the display region.

8. The display device of claim 1, further comprising a display region and a periphery region, wherein the display region comprises a plurality of pixels, and the first thin film transistor unit and the second thin film transistor unit are disposed in one of the pixels.

9. The display device of claim 7, wherein the display region comprises a first pixel and a second pixel adjacent to the first pixel, and the first thin film transistor unit is disposed in the first pixel and the second thin film transistor unit is disposed in the second pixel.

10. The display device of claim 1, wherein the first thin film transistor unit further comprises a first gate electrode corresponding to the first active layer, and the first gate electrode comprises a metal oxide layer.

11. The display device of claim 1, further comprising a first insulating layer, wherein the first insulating layer comprises a silicon nitride layer and the first insulating layer is disposed on the firstactive layer and the second active layer.

12. The display of claim 11, the silicon nitride layer comprises an opening corresponding to second active layer.

13. The display device of claim 1, further comprising a first mask layer, a second mask layer and a buffering layer, wherein the buffering layer is disposed between the first active layer and the substrate, the first mask layer and the second mask layer are disposed between the substrate and the buffering layer, and the first active layer and the second active layer respectively overlap the first mask layer and the second mask layer.

14. The display device of claim 1, wherein the second thin film transistor unit further comprises a second gate electrode corresponding to the second active layer.

15. The display device of claim 14, wherein the second gate electrode has a silicon layer.

16. The display device of claim 1, wherein the first thin film transistor unit further comprises a first gate electrode on the first active layer, and the first gate electrode comprises metal oxide.

17. The display device of claim 1, further comprising a third insulating layer and a fourth insulating layer on the third insulating layer, wherein the third insulating layer comprises a silicon oxide layer, and the fourth insulating layer comprises a silicon nitride layer.

18. The device of claim 17, wherein the first thin film transistor unit further comprises a first gate electrode on the first active layer, the third insulating layer comprising an opening, and the first gate electrode contacts the fourth insulating layer via the opening.

19. The display device of claim 1, wherein the second thin film transistor unit further comprises a second gate electrode below the second active layer.
